(19) United States
(12) Patent Application Publication
(10) Pub. No.: US 2026/0090215 A1
(43) Pub. Date: Mar. 26, 2026

(54) DISPLAY APPARATUS INCLUDING A BANK LAYER AND ELECTRONIC APPARATUS INCLUDING THE SAME

(71) Applicant: SAMSUNG DISPLAY CO., LTD., YONGIN-SI (KR)

(72) Inventor: Hokyun Ahn, YONGIN-SI (KR)

(21) Appl. No.: 19/336,643

(22) Filed: Sep. 23, 2025

(30) Foreign Application Priority Data
Sep. 24, 2024 (KR) 10-2024-0129427

(51) Int. Cl. H10K 59/122; H10K 59/80

(52) U.S. Cl. CPC H10K 59/122; H10K 59/80515

(57) ABSTRACT

Provided is a display panel including a substrate, a first pixel electrode disposed on the substrate, a bank layer covering edges of the first pixel electrode, the bank layer including a first bank layer opening that exposes a central portion of the first pixel electrode, and an intermediate insulating layer disposed between the substrate and the bank layer. The first pixel electrode extends over the intermediate insulating layer. The intermediate insulating layer includes a first insulating pattern overlapping a part of a lateral surface of the first bank layer opening.

### CROSS-REFERENCE TO RELATED APPLICATION

This application is based on and claims priority under 35 U.S.C. §119 to Korean Patent Application No. 10-2024-0129427, filed on September 24, 2024, in the Korean Intellectual Property Office, the disclosure of which is herein incorporated by reference in its entirety.

### TECHNICAL FIELD

The present disclosure relates to a display panel and an electronic apparatus including the same, and more specifically, to the display panel including a bank layer and the electronic apparatus including the same.

### DISCUSSION OF THE RELATED ART

Display panels include a plurality of display elements, and display images by using light emitted from the display elements. In such display panels and electronic apparatuses including such display panels, power consumption is reduced by increasing light extraction efficiency, allowing light generated from emission layers in the display elements to exit the display panel more effectively. For example, by redirecting the light emitted by an emission layer within the display panel, the light extraction efficiency can increase and thus reduce the power consumption

### SUMMARY

According to one or more embodiments of the present disclosure, a display panel includes a substrate, a first pixel electrode disposed on the substrate, a bank layer covering edges of the first pixel electrode, the bank layer including a first bank layer opening that exposes a central portion of the first pixel electrode, and an intermediate insulating layer disposed between the substrate and the bank layer. The first pixel electrode extends over the intermediate insulating layer. The intermediate insulating layer includes a first insulating pattern overlapping a part of a lateral surface of the first bank layer opening.

In an embodiment, the first insulating pattern may overlap about 30 % to about 75 % of the lateral surface of the first bank layer opening facing the first insulating pattern.

In an embodiment, the first insulating pattern may be spaced apart from the first bank layer opening.

In an embodiment, the first bank layer opening may have, in a plan view, a quadrilateral shape, a shape that is similar to quadrilateral but with round corners, or a shape that is similar to quadrilateral but with chamfered edges.

In an embodiment, an end of the first pixel electrode extending towards a center of the lateral surface of the first bank layer opening may be disposed on the first insulating pattern.

In an embodiment, the display panel may further include a thin-film transistor disposed on the substrate, and a planarization layer covering the thin-film transistor and disposed under the first pixel electrode, wherein the intermediate insulating layer is disposed on the planarization layer.

In an embodiment, an end of the first pixel electrode extending towards an edge of the first bank layer opening may be disposed on the planarization layer.

In an embodiment, in a cross-sectional view in a thickness direction of the substrate, an angle between a lateral surface of the first insulating pattern facing the first bank layer opening and an upper surface of the planarization layer ranges from about 45° to about 75°.

In an embodiment, the display panel may further include a second pixel electrode disposed on the substrate, adjacent to the first pixel electrode, wherein the bank layer further includes a second bank layer opening that exposes a central portion of the second pixel electrode, and wherein the intermediate insulating layer further includes a second insulating pattern overlapping a part of a lateral surface of the second bank layer opening.

In an embodiment, the first insulating pattern and the second insulating pattern may be spaced apart from each other.

In an embodiment, the second bank layer opening may include a first lateral surface and a second lateral surface, with a length greater than a length of first lateral surface, and a ratio of a region corresponding to the second insulating pattern to the first lateral surface may be different from a ratio of a region corresponding to the second insulating pattern to the second lateral surface.

In an embodiment, the second insulating pattern may overlap about 30 % to about 75 % of the second lateral surface.

In an embodiment, the second insulating pattern may overlap about 75 % to about 100 % of the first lateral surface.

In an embodiment, the first insulating pattern may include a first sub-pattern and a second sub-pattern that are spaced apart from each other.

In an embodiment, the display panel may further include a thin-film transistor disposed on the substrate, a planarization layer covering the thin-film transistor and disposed under the first pixel electrode, and the intermediate insulating layer and the planarization layer may be integrated into a single structure.

According to one or more embodiments of the present disclosure, an electronic apparatus includes a processor, a memory having stored application programs for execution by the processor, a display device including a display panel, and a user interface configured to sense user input via touch or cursor select of an icon presented on the display panel, wherein the processor is caused to execute one or more of the stored application programs upon receipt of the user input. The display panel includes a substrate, a first pixel electrode disposed on the substrate, a bank layer covering edges of the first pixel electrode, the bank layer including a first bank layer opening that exposes a central portion of the first pixel electrode, and an intermediate insulating layer disposed between the substrate and the bank layer. The first pixel electrode extends over the intermediate insulating layer. The intermediate insulating layer includes a first insulating pattern overlapping a part of a lateral surface of the first bank layer opening.

### BRIEF DESCRIPTION OF THE DRAWINGS

The above and other aspects and features of certain embodiments of the disclosure will be more apparent from the following description taken in conjunction with the accompanying drawings, in which:

FIG. 1A is a schematic perspective view of an electronic apparatus according to an embodiment;

FIG. 1B is a schematic block diagram of an electronic apparatus according to an embodiment of the present disclosure;

FIG. 2 is a schematic perspective view of a display panel according to an embodiment of the present disclosure;

FIGS. 3A and 3B are equivalent circuit diagrams of pixels according to embodiments of the present disclosure, respectively;

FIG. 4 is a plan view of a display panel according to an embodiment of the present disclosure;

FIG. 5 is a cross-sectional view of a display panel according to an embodiment of the present disclosure;

FIG. 6 is a plan view of a display panel according to embodiments of the present disclosure; and

FIG. 7 is a cross-sectional view of a display panel according to embodiments of the present disclosure.

### DETAILED DESCRIPTION

Reference will now be made in detail to embodiments, examples of which are illustrated in the accompanying drawings, wherein like reference numerals may refer to like elements throughout the specification and the figures. In this regard, the present embodiments may have different forms and should not necessarily be construed as being limited to the descriptions set forth herein.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not necessarily limited to the following embodiments and may be embodied in various forms.

While such terms as "first" and "second" may be used to describe various elements, such elements necessarily not be limited to the above terms. The above terms are used to distinguish one element from another.

The singular forms "a," "an," and "the" as used herein are intended to include the plural forms as well unless the context clearly indicates otherwise.

It will be further understood that, when a layer, region, or element is referred to as being "on" another layer, region, or element, it can be directly or indirectly on the other layer, region, or element. That is, for example, intervening layers, regions, or elements may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In the case where a certain embodiment may be implemented differently, a specific process order may be performed in the order different from the described order. As an example, two processes successively described may be simultaneously performed substantially and performed in the opposite order.

It will be understood that when a layer, region, or component is referred to as being "connected" to another layer, region, or component, it may be "directly connected" to the other layer, region, or component or may be "indirectly connected" to the other layer, region, or component with other layer, region, or component interposed therebetween. For example, it will be understood that when a layer, region, or element is referred to as being "electrically connected" to another layer, region, or element, it may be "directly electrically connected" to the other layer, region, or element or may be "indirectly electrically connected" to the other layer, region, or element with another layer, region, or element disposed therebetween.

Embodiments of the present invention relate to a display apparatus and electronic device including the same, aimed at improving a light extraction efficiency.

According to an embodiment of the present disclosure, increased light extraction efficiency may be achieved by the novel arrangement of the constituent elements. In particular, the display apparatus may include pixel electrodes and intermediate insulating layers with slopes.

The intermediate insulating layers include insulating patterns. End portions of the pixel electrodes, which extend horizontally towards the adjacent insulating patterns and away from the central portion of the pixel electrodes, may be disposed on a lateral surface of the insulating pattern. The lateral surface of the insulating pattern where the pixel electrode overlaps may be inclined at an angle. For example, a portion of the pixel electrode may overlap with the lateral surface of the intermediate insulating layer, and the overlapping portion may be sloped.

When light is emitted from the emission layer, it may travel along a horizontal direction. The inclined surface of the insulating pattern, where the pixel electrode is disposed, may reflect the light. After the light is reflected by the inclined portion of the pixel electrode, the light may be redirected towards the front direction of the display, where it may exit the panel.

The redirection of the light may increase the likelihood that more light will escape from the display device, rather than being trapped or absorbed. As a result, a light extraction efficiency of the display apparatus may increase.

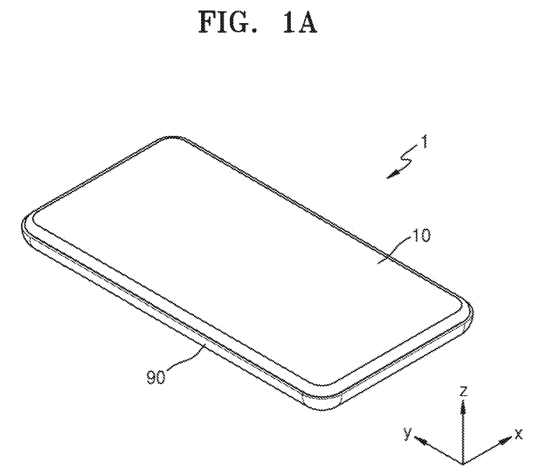

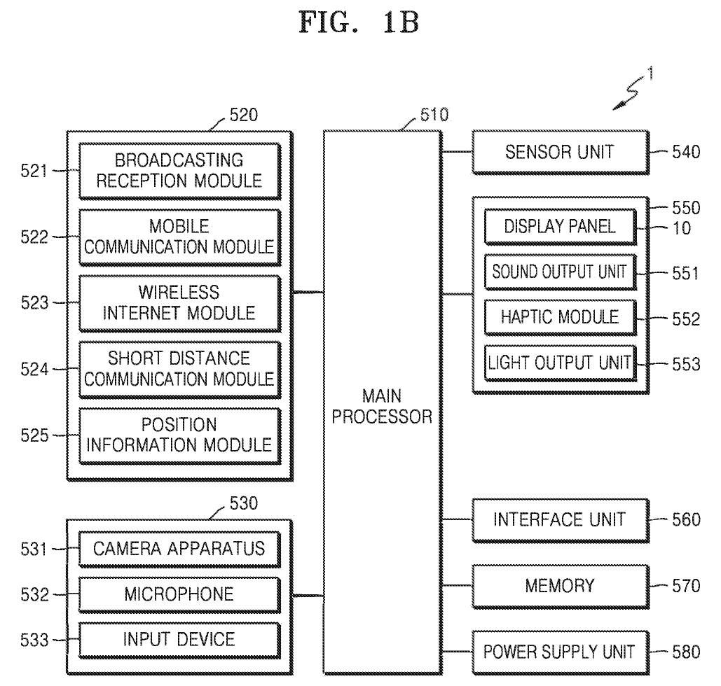

FIG. 1A is a schematic perspective view of an electronic apparatus 1 according to an embodiment, and FIG. 1B is a schematic block diagram of the electronic apparatus 1 according to an embodiment.

Referring to FIGS. 1A and 1B, the electronic apparatus 1 including a display apparatus 10 according to an embodiment is an apparatus displaying moving images or still images and may be used as a display screen of various products including televisions, notebook computers, computer monitors, digital advertisement billboards, Internet of things (IoTs) devices as well as portable electronic apparatuses including mobile phones, smart phones, tablet computers, mobile communication terminals, electronic organizers, electronic books, portable multimedia players (PMPs), navigations, and ultra mobile personal computers (UMPCs). The electronic apparatus 1, according to an embodiment, may be used in wearable devices including smartwatches, watchphones, glasses-type displays, and head-mounted displays (HMDs). The electronic apparatus 1, according to an embodiment, may be used as a display in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

FIG. 1A shows the electronic apparatus 1, according to an embodiment, that is used as a smartphone. The electronic apparatus 1 may include a display panel 10 and a lower cover 90 disposed under the display panel 10. The electronic apparatus 1 may include a cover window covering the upper surface of the display panel 10.

The lower cover 90 may form an exterior of the electronic apparatus 10 and may include an opening exposing a portion of the display panel 10 in a front surface thereof. The lower cover 90 has a shape in which a surface corresponding to the display panel 10 is open, and may be assembled to the display panel 10. The lower cover 90 may form an exterior of the lower surface of the electronic apparatus 1, and a display circuit board, a component, a main circuit board, a battery, a driver, and the like may be disposed between the display panel 10 and the lower cover 90. The lower cover 90 may include plastic, metal, or both plastic and metal.

The electronic apparatus 1 may include a main processor 510, a wireless communication unit 520, an input unit 530, a sensor unit 540, an output unit 550, an interface unit 560, a memory 570, and/or a power supply unit 580.

The main processor 510 may be configured to control all functions of the electronic apparatus 1. As an example, the main processor 510 may be configured to output digital video data to a data driver through the display circuit board such that the display panel 10 displays images. The main processor 510 may be configured to receive sensed data from a touch sensor driver. The main processor 510 may determine whether a user touches a touchscreen according to sensed data, and execute an operation corresponding to a user’s direct touch or proximity touch. The main processor 510 may be an application processor including an integrated circuit, a central processing unit, or a system chip.

A camera apparatus 531 processes image frames such as still images or moving images obtained by an image sensor in a camera mode, and outputs the image frames to the main processor 510. The camera apparatus 531 may include at least one of a camera sensor (e.g., a charge-coupled device (CCD), a complementary metal oxide semiconductor (CMOS), and the like), a photo sensor (or an image sensor), and a laser sensor. The camera apparatus 531 may be connected to the image sensor and may process images input to the image sensor.

The wireless communication unit 520 may include at least one of a broadcasting receiving module 521, a mobile communication module 522, a wireless Internet module 523, a short distance communication module 524, and a position information module 525.

The broadcasting receiving module 521 is configured to receive broadcasting signals and/or broadcasting-related information from an external broadcasting management server through a broadcasting channel. The broadcasting channel may include satellite channels and groundwave channels.

The mobile communication module 522 is configured to transmit/receive radio signals to/from at least one of a base station, an external terminal, and a server on a mobile communication network established according to technology standards for mobile communication or communication schemes (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access(HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module 523 denotes a module for wireless Internet access. The wireless Internet module 523 may be configured to transmit/receive radio signals on a communication network according to wireless Internet technologies. Examples of wireless Internet technologies include wireless local area network (WLAN), wireless-fidelity (Wi-Fi), Wi-Fi Direct, and digital living network alliance (DLNA).

The short distance communication module 524 is for short range communication, and may support short distance communication by using at least one of Bluetooth^{TM}, Radio Frequency Identification (RFID), Infrared Data Association; IrDA (IrDA), Ultra Wideband (UWB), ZigBee, Near Field Communication (NFC), Wi-Fi, Wi-Fi Direct, and Wireless Universal Serial Bus (Wireless USB) technologies. The short distance communication module 524 may support wireless communication between the electronic apparatus 1 and a wireless communication system, between the electronic apparatus 1 and another electronic apparatus, or between the electronic apparatus 1 and a network in which another the electronic apparatus (or an external server) is located, through a short distance wireless area network. The short distance wireless area network may be a wireless personal area network. The other electronic apparatus may be a wearable device that may exchange data, or operate with the electronic apparatus 1.

The position information module 525 is a module for obtaining the position (or the current position) of the electronic apparatus 1, and may include a Global Positioning System (GPS) module or a Wi-Fi module.

The input unit 530 may include an image input unit such as the camera apparatus 531 for inputting image signals, a sound input unit such as a microphone 532 for inputting sound signals, and an input device 533 for receiving information from a user.

The camera apparatus 531 processes image frames such as still images or moving images obtained by an image sensor in an image communication mode or a photographing mode. The processed image frames may be displayed on the display panel 10 or stored in the memory 570.

The microphone 532 processes external sound signals as electrical voice data. The processed voice data may be variously utilized according to a function (or an application in execution) being performed in the electronic apparatus 1.

The main processor 510 may control an operation of the electronic apparatus 1 to correspond to information input through the input device 533. The input device 533 may include a mechanical input means such as buttons, a dome switch, a jog wheel, a jog switch, and the like, or a touch input means located on the lower surface or the lateral surface of the electronic apparatus 1. The touch input means may include a touchscreen layer of the display panel 10.

The sensor unit 540 may include at least one sensor that senses at least one of information inside the electronic apparatus 1, peripheral environmental information surrounding the electronic apparatus 1, and user information, and generates sensing signals corresponding thereto. The main processor 510 may control driving or an operation of the electronic apparatus 1 based on the sensing signals, or perform data processing, a function, or an operation related to an application installed in the electronic apparatus 1. The sensor unit 540 may include at least one of a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, and the like), a chemical sensor (e.g., an electronic nose, a healthcare sensor, a biometric sensor, and the like).

The output unit 550 is for generating an output related to a visual sense, an auditory sense, or a tactile sense, and may include at least one of the display panel 10, a sound output unit 551, a haptic module 552, and a light output unit 553.

The display panel 10 displays (outputs) information processed by the electronic apparatus 1. As an example, the display panel 10 may display execution screen information of an application driven in the electronic apparatus 1, or user interface (UI) and graphic user interface (GUI) information corresponding to execution screen information. The display panel 10 may include a display layer and the touchscreen layer, wherein the display layer displays images, and the touchscreen layer senses a user’s touch input. Accordingly, the display panel 10 may serve as one of the input devices 533 that provide an input interface between the electronic apparatus 1 and a user, and simultaneously, serve as one of the output units 550 that provide an output interface between the electronic apparatus 1 and a user.

The sound output unit 551 may output sound data received by the wireless communication unit 520 or stored in the memory 570 in a signal reception mode, a communication mode or recoding mode, a voice recognition mode, a broadcasting reception mode, and the like. The sound output unit 551 may output sound signals related to a function (e.g., a call signal reception tone, a message reception tone, and the like) performed by the electronic apparatus 1. The sound output unit 551 may include a receiver and a speaker. At least one of the receiver and the speaker may be a sound generator that is attached under the display panel 10 and vibrates the display panel 10 to output sounds. The sound generator may be a piezoelectric element or a piezoelectric actuator that contacts and expands according to electrical signals, or an exciter that generates magnetic force by using a voice coil to vibrate the display panel 10.

The haptic module 552 generates various haptic effects that may be felt by a user. The haptic module 552 may provide vibrations to a user as a haptic effect. The haptic module 552 may not only transfer a tactile effect through a direct contact but implement a tactile effect such that a user may feel the tactile effect through a muscle sense in fingers or arms.

The light output unit 553 outputs signals for informing occurrence of an event by using light of a light source. Examples of an event generated in the electronic apparatus 1 may include message reception, call signal reception, a missed call, alarm, schedule notification, e-mail reception, information reception through an application, and the like. Signals output by the light output unit 553 are implemented when the electronic apparatus 1 emits light of a single color or a plurality of colors to the front surface or the rear surface. The signal output may end when the electronic apparatus 1 detects that a user confirms an event.

The interface unit 560 serves as a path with various kinds of external apparatuses connected to the electronic apparatus 1. The interface unit 560 may include at least one of a wired/wireless headset port, an external charger port, a wired/wireless data port, a memory card part, a port for connecting an apparatus having an identification module, an audio input/output (I/O) port, a video I/O port, and an earphone port. When an external apparatus is connected to the interface unit 560, the electronic apparatus 1 may perform an appropriate control related to the external apparatus connected.

The memory 570 stores data that support various functions of the electronic apparatus 1. The memory 570 may store a plurality of application programs driven in the electronic apparatus 1, data for operations of the electronic apparatus 1, and commands. At least some of the plurality of application programs may be downloaded from an external server through wireless communication. The memory 570 may store an application program for operations of the main processor 510, and temporarily store data input/output, for example, data such as a phone book, messages, still images, moving images, and the like. In addition, the memory 570 may store haptic data for various patterns of vibrations provided to the haptic module 552, and sound data regarding various sounds provided to the sound output unit 551. The memory 570 may include at least one type of storing medium among a flash memory type, a hard disk type, a solid state disk (SSD) type, a silicon disk drive (SDD) type, a multimedia card micro type, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply unit 580 receives an external power and an internal power under control of the main processor 510, and supplies power to respective elements included in the electronic apparatus 1. The power supply unit 580 may include the battery. In addition, the power supply unit 580 includes a connection port. The connection port may be configured as an example of the interface unit 560 to which an external charger is electrically connected, wherein the external charger supplies power to charge the battery. Alternatively, the power supply unit 580 may be configured to charge the battery wirelessly without using the connection port.

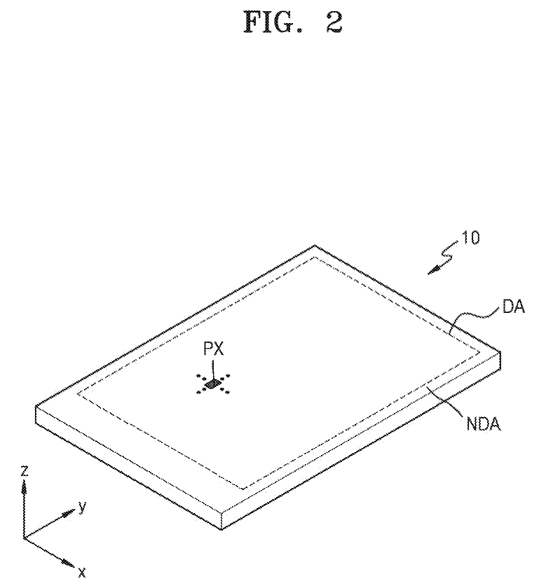

FIG. 2 is a schematic perspective view of the display panel 10 according to an embodiment of the present disclosure.

Referring to FIG. 2, the display panel 10 may include a display area DA and a non-display area NDA. A plurality of pixels PX each including a display element may be disposed in the display area DA. The display panel 10 may display images by using light emitted from the plurality of pixels PX. The non-display area NDA may be a region in which the display elements are not disposed, and may be disposed outside the display area DA. The non-display area NDA may surround the display area DA.

Although FIG. 2 shows the display panel 10 including a flat display surface, the disclosure is not necessarily limited thereto. In an embodiment of the present disclosure, the display panel 10 may include a three-dimensional display surface or a curved display surface. When the display panel 10 includes a three-dimensional display surface, the display panel 10may include a plurality of display areas DA that indicate different directions, such as a polygonal columnar display surface. In an embodiment of the present disclosure, when the display panel 10 includes a curved display surface, the display panel 10 may be implemented in various forms, such as a flexible, foldable, or rollable display panel.

While the display area DA of the display panel 10 is shown as quadrilateral in FIG. 1, the display area DA may have circular, elliptical, or polygonal shape, such as triangle or pentagon.

Hereinafter, although an organic light-emitting display panel is described as an example of the display panel 10, the display panel 10 according to the present disclosure is not necessarily limited thereto. In an embodiment of the present disclosure, the display panel 10 may be an inorganic light-emitting display panel or a quantum-dot light-emitting display panel. For example, an emission layer of a display element provided to the display panel 10 may include an organic material, an inorganic material, quantum dots, the combination thereof.

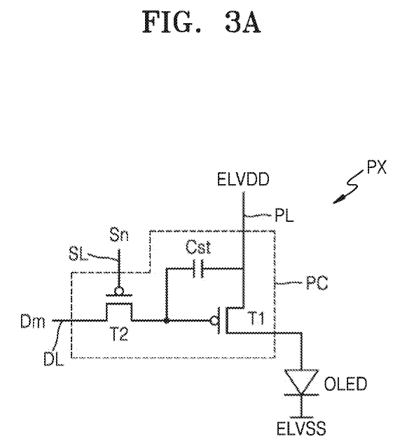

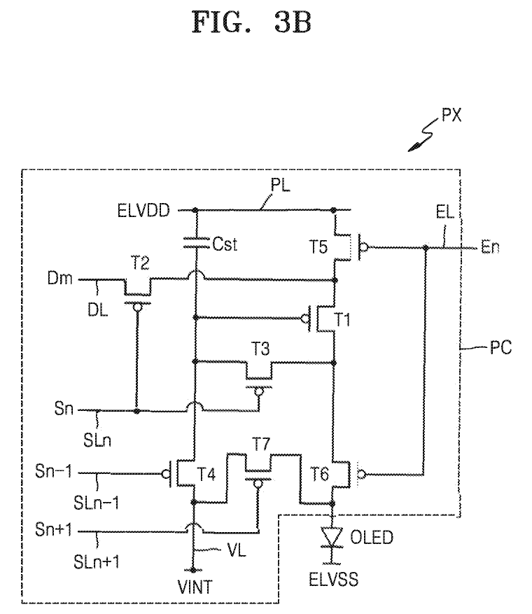

FIGS. 3A and 3B illustrate circuit diagrams of a pixel according to embodiments of the present disclosure.

Referring to FIG. 3A, each pixel PX may include a pixel circuit PC and an organic light-emitting diode OLED connected to the pixel circuit PC. The pixel circuit PC is connected to a scan line SL and a data line DL.

The pixel circuit PC may include a driving transistor T1, a switching transistor T2, and a storage capacitor Cst. The switching transistor T2 may be connected to the scan line SL and the data line DL, and may transfer a data signal Dm to the driving transistor T1 based on a scan signal Sn. The data signal Dm may be input through the data line DL, and the scan signal Sn may be input through the scan line SL.

The storage capacitor Cst may be connected to the switching transistor T2 and a driving voltage line PL, and may be configured to store a voltage corresponding to a difference between a voltage transferred from the switching transistor T2 and a driving voltage ELVDD supplied to the driving voltage line PL.

The driving transistor T1 may be connected to the driving voltage line PL and the storage capacitor Cst, and may be configured to control a driving current based on the voltage stored in the storage capacitor Cst, which is the driving current flowing from the driving voltage line PL to the organic light-emitting diode OLED. The organic light-emitting diode OLED may be configured to emit light having a preset brightness corresponding to the driving current.

Although it is described with reference to FIG. 3A that the pixel PX includes two transistors T1 and T2 and one storage capacitor Cst, the number of transistors T1 and T2 and the number of storage capacitor Cst is not necessarily limited thereto.

Referring to FIG. 3B, the pixel circuit PC may include the driving transistor T1, the switching transistors T2, a compensation transistor T3, a first initialization transistor T4, a first emission control transistor T5, a second emission control transistor T6, and a second initialization transistor T7.

A drain electrode of the driving transistor T1 may be electrically connected to the organic light-emitting diode OLED through the second emission control transistor T6. The driving transistor T1 may be configured to receive a data signal Dm and supply the driving current to the organic light-emitting diode OLED based on a switching operation of the switching transistor T2.

A gate electrode of the switching transistor T2 may be electrically connected to the scan line SL, and a source electrode may be electrically connected to the data line DL. A drain electrode of the switching transistor T2 may be electrically connected to the source electrode of the driving transistor T1, and electrically connected to the driving voltage line PL through the first emission control transistor T5.

The switching transistor T2 may be turned on based on a scan signal Sn transferred through the scan line SL and may perform a switching operation of transferring a data signal Dm to the source electrode of the driving transistor T1. The data signal Dm may be transferred to the data line DL.

A gate electrode of the compensation transistor T3 may be electrically connected to a scan line SLn. A source electrode of the compensation transistor T3 may be electrically connected to the drain electrode of the driving transistor T1 and may be electrically connected to a pixel electrode of the organic light-emitting diode OLED through the second emission control transistor T6. A drain electrode of the compensation transistor T3 may be electrically connected to one of electrodes of the storage capacitor Cst, a source electrode of the first initialization transistor T4, and a gate electrode of the driving transistor T1. The compensation transistor T3 may be turned on based on a scan signal Sn received through the scan line SL and may diode-connect the driving transistor T1 by connecting the gate electrode and the drain electrode of the driving transistor T1 to each other.

A gate electrode of the first initialization transistor T4 may be electrically connected to a second scan line SLn-1. A drain electrode of the first initialization transistor T4 may be electrically connected to an initialization voltage line VL. A source electrode of the first initialization transistor T4 may be electrically connected to one of the electrodes of the storage capacitor Cst, the drain electrode of the compensation transistor T3, and the gate electrode of the driving transistor T1. For example, the first initialization transistor T4 may be turned on based on a second scan signal Sn-1 received through the second scan line SLn-1 and may perform an initialization operation of initializing the voltage of the gate electrode of the driving transistor T1 by transferring an initialization voltage VINT to the gate electrode of the driving transistor T1.

A gate electrode of the first emission control transistor T5 may be electrically connected to an emission control line EL. A source electrode of the first emission control transistor T5 may be electrically connected to the driving voltage line PL. A drain electrode of the first emission control transistor T5 may be electrically connected to the source electrode of the driving transistor T1 and the drain electrode of the switching transistor T2.

A gate electrode of the second emission control transistor T6 may be electrically connected to the emission control line EL. A source electrode of the second emission control transistor T6 may be electrically connected to the drain electrode of the driving transistor T1 and the source electrode of the compensation transistor T3. A drain electrode of the second emission control transistor T6 may be electrically connected to the pixel electrode of the organic light-emitting diode OLED. The first emission control transistor T5 and the second emission control transistor T6 may be simultaneously turned on based on an emission control signal En transferred through the emission control line EL. This may transfer the driving voltage ELVDD to the organic light-emitting diode OLED, and the driving current may flow through the organic light-emitting diode OLED.

A gate electrode of the second initialization transistor T7 may be electrically connected to a third scan line SLn+1. A source electrode of the second initialization transistor T7 may be electrically connected to the pixel electrode of the organic light-emitting diode OLED. A drain electrode of the second initialization transistor T7 may be electrically connected to the initialization voltage line VL. The second initialization transistor T7 may be turned on based on a third scan signal Sn+1 transferred through the third scan line SLn+1 and may initialize the pixel electrode of the organic light-emitting diode OLED. Throughout the specification, n is a positive integer.

Other electrodes of the storage capacitor Cst may be connected to the driving voltage line PL. One of the electrodes of the storage capacitor Cst may be connected to the gate electrode of the driving transistor T1, the drain electrode of the compensation transistor T3, and the source electrode of the first initialization transistor T4.

An opposite electrode 315 of the organic light-emitting diode OLED may be configured to receive a common power voltage ELVSS. The organic light-emitting diode OLED may be configured to emit light by receiving the driving current from the driving transistor T1.

The pixel circuit PC is not necessarily limited to the number of thin-film transistors 210, the number of storage capacitors Cst. The circuit design described with reference to FIGS. 3A and 3B, and the number of thin-film transistors, the number of storage capacitors, and the circuit design may vary.

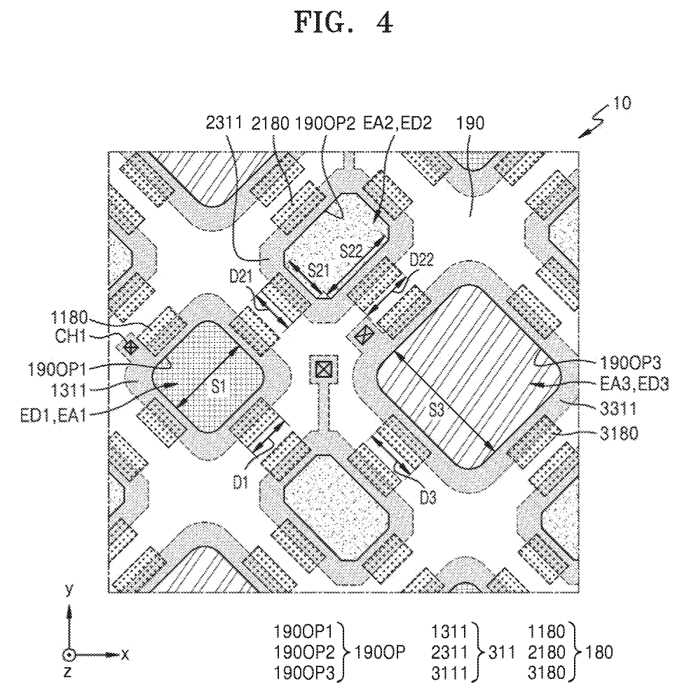

FIG. 4 is a plan view of the display panel 10 according to an embodiment of the present disclosure. FIG. 4 is a schematic enlarged plan view of a partial region of the display area DA (see FIG. 2). For convenience, FIG. 4 shows a plan view of a bank layer 190.

Referring to FIG. 4, the display panel 10 may include a plurality of light-emitting elements ED1, ED2, and ED3. The plurality of light-emitting elements ED1, ED2, and ED3 may include a first light-emitting element ED1, a second light-emitting element ED2, and a third light-emitting element ED3. The first light-emitting element ED1, the second light-emitting element ED2, and the third light-emitting element ED3 may respectively emit light of different colors. For example, the first light-emitting element ED1 may be configured to emit red light, the second light-emitting element ED2 may be configured to emit green light, and the third light-emitting element ED3 may be configured to emit blue light. Red light may be light in a wavelength band ranging from about 600 nm to about 780 nm, green light may be light in a wavelength band ranging from about 495 nm to about 600 nm, and blue light may be light in a wavelength band ranging from about 380 nm to about 495 nm. Each of the first light-emitting element ED1, the second light-emitting element ED2, and the third light-emitting element ED3 may correspond to the organic light-emitting diode OLED illustrated in FIG. 3A.

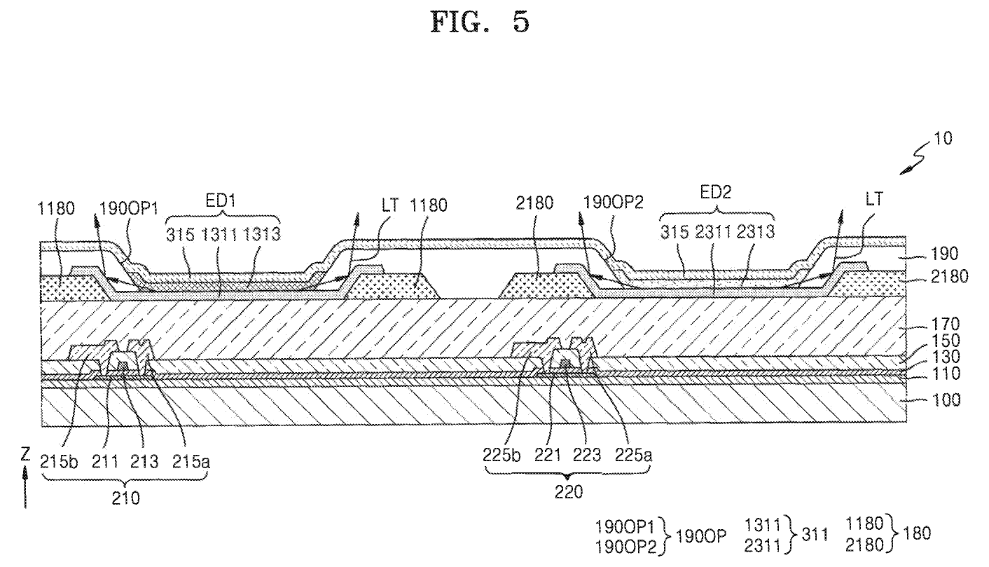

Each of the first light-emitting element ED1, the second light-emitting element ED2, and the third light-emitting element ED3 may include a pixel electrode 311, the opposite electrode 315, and an emission layer disposed therebetween. Accordingly, the first light-emitting element ED1 may include a first pixel electrode 1311, and the second light-emitting element ED2 may include a second pixel electrode 2311, and the third light-emitting element ED3 may include a third pixel electrode 3311. The first to third pixel electrodes 1311, 2311, and 3311 may be spaced apart from each other and may be disposed on the substrate 100 (see FIG. 5). In the present specification, "on a plane" refers to a plane viewed from a direction perpendicular to the substrate 100 (see FIG. 5). For example, "A and B spaced apart from each other on a plane" means "A and B apart from each other when viewed in a direction perpendicular to the substrate 100 (see FIG. 5)."

The bank layer 190 may be disposed on the first to third pixel electrodes 1311, 2311, and 3311 and may cover the edges of each of the first to third pixel electrodes 1311, 2311, and 3311. For example, the bank layer 190 may include a plurality of bank layer openings 190OP exposing the central portion of each of the plurality of pixel electrodes 311. For example, the bank layer 190 may include a first bank layer opening 190OP1 exposing the central portion of the first pixel electrode 1311, a second bank layer opening 190OP2 exposing the central portion of the second pixel electrode 2311, and a third bank layer opening 190OP3 exposing the central portion of the third pixel electrode 3311.

Emission layers emitting light LT may be respectively disposed in the first to third bank layer openings 190OP1, 190OP2, and 190OP3 of the bank layer 190. The opposite electrode 315 may be disposed on the emission layers and active layers. As described above, a stack structure of the pixel electrode 311, the emission layer, and the opposite electrode 315 may form a single light-emitting element ED1 or ED2. One bank layer opening 190OP of the bank layer 190 may correspond to a single light-emitting element ED1, ED2, or ED3 and define a single emission area EA1, EA2, or EA3.

For example, an emission layer emitting red light may be disposed in the first bank layer opening 190OP1, and the first bank layer opening 190OP1 may define a first emission area EA1. Similarly, an emission layer emitting green light may be disposed in the second bank layer opening 190OP2, and the second bank layer opening 190OP2 may define a second emission area EA2. An emission layer emitting blue light may be disposed in the third bank layer opening 190OP3, and the third bank layer opening 190OP3 may define a third emission area EA3. Accordingly, the size of the area of the first bank layer opening 190OP1 may be the same as the size of the area of the first emission area EA1. The size of the area of the second bank layer opening 190OP2 may be the same as the size of the area of the second emission area EA2, and the size of the area of the third bank layer opening 190OP3 may be the same as the size of the area of the third emission area EA3.

Each of the first to third bank layer openings 190OP1, 190OP2, and 190OP3 may have a polygonal shape when viewed from a direction (z axis direction) perpendicular to the substrate 100 (see FIG. 5). For example, each of the first to third emission areas EA1, EA2, and EA3 may have a polygonal shape when viewed from the direction (z axis direction) perpendicular to the substrate 100. In an embodiment of the present disclosure, each of the first to third emission areas EA1, EA2, and EA3 may have a quadrangular shape with round corners, or a chamfered quadrangular shape with corners cut off at an angle, in a plan view. For example, as shown in FIG. 4, the first emission area EA1 and the third emission area EA3 may have a quadrangular shape with round corners in a plan view, and the second emission area EA2 may have a chamfered quadrangular shape with corners cut off at an angle in a plan view. However, the embodiment of the present disclosure is not necessarily limited thereto and each of the first to third emission areas EA1, EA2, and EA3 may have a circular shape or an elliptical shape in a plan view.

The display panel 10 includes an array of light-emitting elements ED1, ED2, and ED3 disposed in the display area DA. The array of light-emitting elements ED1, ED2, and ED3 may include the first to third light-emitting elements ED1, ED2, and ED3 arranged two-dimensionally. In an embodiment of the present disclosure, the array of light-emitting elements ED1, ED2, and ED3 may have a minimal repeating unit in which the first to third light-emitting elements ED1, ED2, and ED3 are repeatedly arranged along a first direction (e.g., an x direction) and a second direction (e.g., a y direction). The minimal repeating unit may be a repeating unit that includes the fewest number of sub-pixels.

For example, the light-emitting elements ED1, ED2, and ED3 disposed on the display panel 10 may be disposed in a diamond pentile form. As shown in FIG. 4, the diamond pentile form may refer to a layout where in the first light-emitting element ED1 and the third light-emitting element ED3 may be disposed alternately in the same row along the first direction (e.g., x direction) and the second light-emitting element ED2 may be arranged in an adjacent row, creating a staggered arrangement between the light-emitting elements ED1, ED2, and ED3. For example, the first light-emitting element ED1 and the second light-emitting element ED2 may be alternately disposed along a diagonal direction, while the third light-emitting element ED3 and the second light-emitting element ED2 may also alternate along a diagonal direction. For example, each of the first and the third light emitting elements ED1 and ED3 is disposed at the center of a square formed by four second light-emitting elements ED2, each located adjacent to the others..

An intermediate insulating layer 180 may be disposed between the substrate 100 (see FIG. 5) and the bank layer 190. The intermediate insulating layer 180 may be disposed adjacent to the bank layer opening 190OP, but spaced apart from the bank layer opening 190OP in a plan view. The pixel electrode 311 may extend to be disposed on the intermediate insulating layer 180. The pixel electrode 311 may at least partially overlap the intermediate insulating layer 180. For example, a part of the edge of the pixel electrode 311 may be disposed on the intermediate insulating layer 180. Although described below with reference to FIG. 5, among lateral surfaces of the intermediate insulating layer 180, a lateral surface of the intermediate insulating layer 180 facing the bank layer opening 190OP may be inclined. (Hereinafter, the lateral surface of the intermediate insulating layer 180 facing the bank layer opening 190OP will be referred to an inner surface.) In this case, the pixel electrode 311 may be positioned on the inclined inner surface of the intermediate insulating layer 180. For example, at least a portion of the pixel electrode 311 may overlap with the inner surface of the intermediate insulating layer 180, and the overlapping portion may be inclined. Through this structure, light LT emitted from the emission layer and moving in a lateral direction may be reflected by the pixel electrode 311, which is positioned on the inner surface of the intermediate insulating layer 180, and then may be redirected to move along a front direction (e.g., z direction) of the display panel 10.

In an embodiment of the present disclosure, the intermediate insulating layer 180 may include insulating pattern 1180,2180, and 3180, which corresponds to a part of the lateral surface of the bank layer opening 190OP in a plan view. For example, the intermediate insulating layer 180 may include a first insulating pattern 1180 that corresponds to a partial region of the lateral surface of the first bank layer opening 190OP1 in a plan view. For example, the intermediate insulating layer 180 may include a second insulating pattern 2180 that corresponds to a part the lateral surface of the second bank layer opening 190OP2, and a third insulating pattern 3180 disposed that corresponds to a part of the lateral surface of the third bank layer opening 190OP3 in a plan view.

In an embodiment of the present disclosure, in the case where the bank layer opening 190OP has a quadrangular shape in a plan view, four insulating patterns 1180, 2180, or 3180 may be disposed adjacent to the bank layer opening 190OP. For example, the first bank layer opening 190OP1 may have four lateral surfaces, and four first insulating patterns 1180 may be respectively disposed adjacent to each of the four lateral surfaces. However, the embodiment is not necessarily limited thereto, and the number of insulating patterns 1180, 2180, and 3180 disposed adjacent to the bank layer opening 190OP may vary depending on a planar shape of the bank layer opening 190OP.

In an embodiment of the present disclosure, the first insulating pattern 1180 may overlap about 30 % to about 75 % of the lateral surface of the first bank layer opening 190OP1. For example, as shown in FIG. 4, the lateral surface of the first bank layer opening 190OP1 may have a first opening length S1 in a plan view. Among four lateral surfaces of the first insulating pattern 1180, the lateral surface of the first insulating pattern 1180 facing the first bank layer opening 190OP1 may have a first pattern length D1 in a plan view. In this case, the first pattern length D1 may have a length within the range of about 30 % to about 75 % of the first opening length S1.

For example, the first insulating pattern 1180 may not cover the entire lateral surface of the first bank layer opening 190OP1 but may cover a portion of the lateral surface of the first bank layer opening 190OP1. For example, the first insulating pattern 1180 may be disposed in only the outer region of the lateral surface of the first bank layer opening 190OP1 and may not be disposed in the outer region of the edge of the first bank layer opening 190OP1. Accordingly, an end of the first pixel electrode 1311, which extends toward the central region of the lateral surface of the first bank layer opening 190OP1, may be disposed on the first insulating pattern 1180. An end of the first pixel electrode 1311, which extends toward an edge of the first bank layer opening 190OP1, may be disposed on a planarization layer 170 (see FIG. 5) as described below.

In an embodiment of the present disclosure, a planar area of the third emission area EA3 emitting blue light may be greater than a planar area of the first emission area EA1 emitting red light. Even in this case, the third insulating pattern 3180 may overlap about 30 % to about 75 % of the lateral surface of the third bank layer opening 190OP3. For example, as shown in FIG. 4, the lateral surface of the third bank layer opening 190OP3 may have a third opening length S3 in a plan view, and among lateral surfaces of the third insulating pattern 3180, a lateral surface of the third insulating pattern 3180 facing the third bank layer opening 190OP3 may have a third pattern length D3 in a plan view. In this case, the third pattern length D3 may have a length within the range of about 30 % to about 75 % of the third opening length S3.

For example, the third insulating pattern 3180 may not cover the entire lateral surface of the third bank layer opening 190OP3 but may cover a portion of the lateral surface of the third bank layer opening 190OP3. For example, the third insulating pattern 3180 may be disposed in only the outer region of the lateral surface of the third bank layer opening 190OP3 and may not be disposed in the outer region of the edge of the third bank layer opening 190OP3. Accordingly, an end of the third pixel electrode 3311, which extends toward the central region of the lateral surface of the first bank layer opening 190OP3, may be disposed on the first insulating pattern 3180. An end of the third pixel electrode 3311, which extends toward an edge of the first bank layer opening 190OP3, may be disposed on a planarization layer 170 (see FIG. 5) as described below.

In an embodiment of the present disclosure, the second bank layer opening 190OP2 may have a first lateral surface and a second lateral surface. The second lateral surface may have a length greater than the first lateral surface. For example, the second bank layer opening 190OP2 may have a chamfered rectangular shape in a plan view, and the second bank layer opening 190OP2 may have two short sides and two long sides in a plan view. Hereinafter, the first lateral surface may refer to the short side of the second bank layer opening 190OP2 and the second lateral surface may refer to the long side of the second bank layer opening 190OP2. In this case, a ratio of a region overlapping the second insulating pattern 2180 on the first lateral surface may be different from a ratio of a region overlapping the second insulating pattern 2180 on the second lateral surface.

In an embodiment of the present disclosure, the second insulating pattern 2180 may be disposed to overlap about 30 % to about 75 % of the second lateral surface. For example, as shown in FIG. 4, the second lateral surface of the second bank layer opening 190OP2 may have a second-2 opening length S22 in a plan view. Among lateral surfaces of the second insulating pattern 2180, a lateral surface of the second insulating pattern 2180 facing the second bank layer opening 190OP2 may have a second-2 pattern length D22 in a plan view. In this case, the second-2 pattern length D22 may have a length within the range of about 30 % to about 75 % of the second-2 opening length S22.

In an embodiment of the present disclosure, the second insulating pattern 2180 may overlap about 75 % to about 100 % of the first lateral surface corresponding to a short side. For example, as shown in FIG. 4, the first lateral surface of the second bank layer opening 190OP2 may have a second-1 opening length S21 in a plan view. Among lateral surfaces of the second insulating pattern 2180, a lateral surface of the second insulating pattern 2180 facing the second bank layer opening 190OP2 may have a second-1 pattern length D21 in a plan view. In this case, the second-1 pattern length D21 may have a length within the range of about 75 % to about 100 % of the second-1 opening length S21.

As described above, because the intermediate insulating layer 180 is disposed adjacent to the bank layer opening 190OP, light LT emitted along the lateral direction from the emission layer may be reflected by the pixel electrode 311, which is disposed on the inner surface of the intermediate insulating layer 180, and emitted to the front direction of the display panel 10. Accordingly, a light extraction efficiency may increase. In this case, the inner surface of the intermediate insulating layer 180 may be inclined such that light LT emitted to the lateral surface is reflected by the pixel electrode 311 and emitted to the front direction of the display panel 10. As a planar length of the inner surface of the intermediate insulating layer 180 increases, it may be difficult for the inner surface of the intermediate insulating layer 180 to have a high slope. For example, as the planar length of the inner surface of the intermediate insulating layer 180 is reduced, the slope of the inner surface of the intermediate insulating layer 180 may increase.

Accordingly, in the display panel 10 according to an embodiment of the present disclosure, the insulating pattern 1180, 2180, and 3180 of the intermediate insulating layer 180 may overlap a part of the lateral surface of the bank layer opening 190OP, thereby increasing a slope of the inner surface of the intermediate insulating layer 180. As described above, the first insulating pattern 1180 may overlap about 30 % to about 75 % of the lateral surface of the first bank layer opening 190OP1. For example, the first pattern length D1 of the first insulating pattern 1180 may be adjusted to overlap within the range of about 30 % to about 75 % of the lateral surface of the first bank layer opening 190OP1 to form a desired slope of the inner surface of the intermediate insulating layer 180. For example, the third pattern length D3 of the third insulating pattern 3180 may be adjusted within the range of about 30 % to about 75 % to form a desired slope of the inner surface of the intermediate insulating layer 180.

In a case where the second insulating pattern 2180 overlaps a long side of the second bank layer opening 190OP2, the second-2 pattern length D22 may be adjusted to overlap within the range of about 30 % to about 75 % of the lateral surface of the second bank layer opening 199OP2 to form a desired slope of the inner surface of the intermediate insulating layer 180. However, like the second insulating pattern 2180 disposed to overlap a short side of the second bank layer opening 190OP2, if the length of the short side of the second bank layer opening 190OP2 is sufficiently short, the second insulating pattern 2180 may be formed such that the inner surface of the intermediate insulating layer 180 has a desired slope. In this case, the second insulating pattern 2180 may overlap the entire first lateral surface of the second bank layer opening 190P2, rather than just a partial region. Accordingly, the second-1 pattern length D21 of the second insulating pattern 2180 may be adjusted to overlap within the range of about 75 % to about 100 % of the lateral surface of the second bank layer opening 190OP2 to form a desired slope of the inner surface of the intermediate insulating layer 180.

In the display panel 10 according to an embodiment of the present disclosure, because the intermediate insulating layer 180 may include the first to third insulating patterns 1180, 2180, and 3180, a light extraction efficiency may increase by adjusting a slope of the inner surface of the intermediate insulating layer 180.

FIG. 5 is a cross-sectional view of the display panel 10 according to an embodiment of the present disclosure.

Referring to FIG. 5, the display panel 10 may include the substrate 100, the first light-emitting element ED1, and the second light-emitting element ED2 disposed over the substrate 100.

The substrate 100 may include various flexible or bendable materials, such as a polymer resin including polyethersulphone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), or cellulose acetate propionate (CAP). The substrate 100 may have a multi-layered structure including two layers each including the polymer resin, and a barrier layer including an inorganic material (such as silicon oxide, silicon nitride, or silicon oxynitride) therebetween. However, it is not necessarily limited thereto, and various modifications may be made. Furthermore, in the case where the substrate 100 is not bent, the substrate 100 may include glass and the like.

The first light-emitting element ED1 may be disposed over the substrate 100, and a first pixel circuit may be disposed between the substrate 100 and the first light-emitting element ED1. The first pixel circuit may be electrically connected to the first light-emitting element ED1 to control an emission degree thereof. The second light-emitting element ED2 may be disposed over the substrate 100, and a second pixel circuit may be disposed between the substrate 100 and the second light-emitting element ED2. The second pixel circuit may be electrically connected to the second light-emitting element ED2. FIG. 5 shows, as an example, a first thin-film transistor 210 may be provided on the first pixel circuit, and a second thin-film transistor 220 may be provided on the second pixel circuit. Hereinafter, the first thin-film transistor 210 and the second thin-film transistor 220 may have a similar structure. For convenience of description, the first thin-film transistor 210 will be mainly described.

As shown in FIG. 5, the first thin-film transistor 210 may include a semiconductor layer 211, a gate electrode 213, a source electrode 215a, and a drain electrode 215b. The semiconductor layer 211 may include amorphous silicon, polycrystalline silicon, or an organic semiconductor material. Although it is shown in FIG. 5 that the first thin-film transistor 210 includes the first source electrode 215a and the first drain electrode 215b, the disclosure is not necessarily limited thereto. For example, the source electrode 215a and/or the drain electrode 215b may be a portion of a wiring. In an embodiment of the present disclosure, the first thin-film transistor 210 may not include the source electrode 215a and/or the drain electrode 215b. Instead, a source region of the semiconductor layer 211 may serve as a source electrode, or a drain region may serve as a drain electrode. For example, the first thin-film transistor 210 may not include a source electrode 215a, and the source region of the semiconductor layer 211. Instead, the first thin-film transistor 210 may be integrally formed with a drain region of another thin-film transistor. In this case, the first thin-film transistor 210 may not include a source electrode and the other thin-film transistor may not include a drain electrode, but it may be shown in the pixel circuit diagram that the drain electrode of the other thin-film transistor is electrically connected to the source electrode of the first thin-film transistor 210. This is also applicable to embodiments below and modifications thereof.

To secure insulation between the semiconductor layer 211 and the gate electrode 213, a gate insulating layer 130 may be disposed between the semiconductor layer 211 and the gate electrode 213. The gate insulating layer 130 may include an inorganic material such as silicon oxide, silicon nitride, and/or silicon oxynitride. An interlayer insulating layer 150 may be disposed on the gate electrode 213. The interlayer insulating layer 150 may include an inorganic material such as silicon oxide, silicon nitride, and/or silicon oxynitride. The source electrode 215a and the drain electrode 215b may be disposed on the interlayer insulating layer 150. The insulating layer may include an inorganic material that is formed though chemical vapor deposition (CVD) or atomic layer deposition (ALD). This is also applicable to embodiments below and modifications thereof.

A buffer layer 110 may be disposed between the first thin-film transistor 210 and the substrate 100. The buffer layer 110 may include an inorganic material such as silicon oxide, silicon nitride, and/or silicon oxynitride. The buffer layer 110 may increase the flatness of the upper surface of the substrate 100, or prevent or reduce the penetration of impurities from the substrate 100 or the like into the semiconductor layer 211 of the first thin-film transistor 210.

The gate electrode 213 may include, for example, metal such as molybdenum or aluminum and may be formed using a method such as sputtering. The gate electrode 213 may have a single-layered structure or a multi-layered structure. For example, the gate electrode 213 may have a two-layered structure of molybdenum and aluminum. The source electrode 215a and the drain electrode 215b may include metal such as titanium or aluminum and have a single-layered structure or a multi-layered structure. For example, the source electrode 215a and the drain electrode 215b may have a three-layered structure of titanium, aluminum, and titanium.

The planarization layer 170 may be disposed on the first thin-film transistor 210. For example, the planarization layer 170 may cover at least a portion of the first thin-film transistor 210. For example, as shown in FIG. 5, in the case where the first light-emitting element ED1 is disposed on the first thin-film transistor 210, the planarization layer 170 may generally planarize the upper portion of the first thin-film transistor 210. The planarization layer 170 may include an organic material, for example, acryl, benzocyclobutene (BCB), or hexamethyldisiloxane (HMDSO). Although it is shown in FIG. 5 that the planarization layer 170 is a single layer, the planarization layer 170 may be a multi-layer.

The first light-emitting element ED1 and the second light-emitting element ED2 may be disposed on the planarization layer 170. The first light-emitting element ED1 may include the first pixel electrode 1311, a opposite electrode 315, and a first intermediate layer 1313. The first intermediate layer 1313 may be disposed between the first pixel electrode 1311 and the opposite electrode 315. The second light-emitting element ED2 may include the second pixel electrode 2311, the opposite electrode 315, and a second intermediate layer 2313. The second intermediate layer 2313 may be disposed between the second pixel electrode 2311 and the opposite electrode 315.

The first pixel electrode 1311 and the second pixel electrode 2311 may be disposed on the planarization layer 170. The first pixel electrode 1311 may be electrically connected to the first thin-film transistor 210 through a contact hole CH1 (see FIG. 4) formed in the planarization layer 170, and the second pixel electrode 2311 may be also electrically connected to the second thin-film transistor 220 through a contact hole formed in the planarization layer 170. The first pixel electrode 1311 and the second pixel electrode 2311 may include a light-transmissive conductive layer and a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). For example, each of the first pixel electrode 1311 and the second pixel electrode 2311 may have a three-layered structure of indium tin oxide, silver, and indium tin oxide.

The bank layer 190 may be disposed on the planarization layer 170. The bank layer 190 may define an emission area EA1, EA2, and EA3 by including the first bank layer opening 190OP1 exposing the central portion of the first pixel electrode 1311 and the second bank layer opening 190OP2 exposing the central portion of the second pixel electrode 2311. In addition, as shown in FIG. 5, the bank layer 190 may prevent arcs and the like from occurring at the edges of the first pixel electrode 1311 by increasing a distance between the edges of the first pixel electrode 1311 and the opposite electrode 315. The bank layer 190 may include an organic material such as polyimide or HMDSO.

The intermediate insulating layer 180 may be disposed between the planarization layer 170 and the bank layer 190. As described above, the intermediate insulating layer 180 may include the first insulating pattern 1180 disposed adjacent to the first bank layer opening 190OP1, and the second insulating pattern 2180 disposed adjacent to the second bank layer opening 190OP2. The first insulating pattern 1180 may be disposed apart from the first bank layer opening 190OP1 in a plan view, and the second insulating pattern 2180 may be disposed apart from the second bank layer opening 190OP2 in a plan view. For example, the inner surface of the first insulating pattern 1180 may be disposed further away from the center of the first bank layer opening 190OP1 than the inner surface of the bank layer 190. The inner surface of the second insulating pattern 2180 may be disposed further away from the center of the second bank layer opening 190OP2 than the inner surface of the bank layer 190.

In an embodiment of the present disclosure, the first insulating pattern 1180 and the second insulating pattern 2180 may be disposed apart from each other. The bank layer 190 may fill a space by which the first insulating pattern 1180 and the second insulating pattern 2180 are apart from each other. For example, the bank layer 190 may be in direct contact with the planarization layer 170 in a region between the first light-emitting element ED1 and the second light-emitting element ED2.

The edges of the first pixel electrode 1311 and the second pixel electrode 2311 may be disposed on the intermediate insulating layer 180. Accordingly, each of a portion of the first pixel electrode 1311 and a portion of the second pixel electrode 2311 may be disposed on the inner surface of the intermediate insulating layer 180. In addition, because the intermediate insulating layer 180 is spaced apart from the bank layer opening 190OP, the bank layer 190 may cover an edge portion of the pixel electrode 311, which is disposed on the inner surface of the intermediate insulating layer 180. However, as described above with reference to FIG. 4, each of the first insulating pattern 1180 and the second insulating pattern 2180 may cover a partial region of the lateral surface of the bank layer opening 190OP and not cover the entire lateral surface of the bank layer opening 190OP. Accordingly, the edge of the pixel electrode 311 may be disposed on the planarization layer 170 in a region in which the insulating pattern 1180, 2180, or 3180 is not disposed, that is, a region adjacent to the edge of the bank layer opening 190OP.

Each of the first intermediate layer 1313 and the second intermediate layer 2313 may include an emission layer and a functional layer. Each of the first intermediate layer 1313 and the second intermediate layer 2313 may include a low molecular weight material or a polymer material. In the case where the first intermediate layer 1313 and the second intermediate layer 2313 include a low molecular weight material, each of the first intermediate layer 1313 and the second intermediate layer 2313 may have a structure in which a hole injection layer (HIL), a hole transport layer (HTL), a first emission layer (EML), an electron transport layer (ETL), an electron injection layer (EIL) are stacked in a single structure or composite structure, and may be formed using vacuum deposition. In the case where the first intermediate layer 1313 and the second intermediate layer 2313 include a polymer material, the first intermediate layer 1313 and the second intermediate layer 2313 may have a structure including an HTL and an EML. In this case, the HTL may include poly (3, 4-ethylenedioxythiophene) (PEDOT), and the first EML may include a polymer material such as a polyphenylene vinylene (PPV)-based material and a polyfluorene-based material. Each of the first intermediate layer 1313 and the second intermediate layer 2313 may be formed using screen printing, inkjet printing, laser induced thermal imaging (LITI), and the like.

The first intermediate layer 1313 and the second intermediate layer 2313 are not necessarily limited to the above-mentioned structure and may have various structures. In addition, an emission layer of the first intermediate layer 1313 and the second intermediate layer 2313 may have a shape corresponding to the pixel electrode 311, but layers other than the emission layer of the first intermediate layer 1313 and the second intermediate layer 2313 may be integrally formed over the first pixel electrode 1311 and the second pixel electrode 2311. The first intermediate layer 1313 may be in contact with the first pixel electrode 1311 through the first bank layer opening 190OP1 of the bank layer 190, and the second intermediate layer 2313 may be in contact with the second pixel electrode 2311 through the second bank layer opening 190OP2 of the bank layer 190.

The opposite electrode 315 may be disposed in the display area DA (see FIG. 2) in which the plurality of light-emitting elements ED1, ED2, and ED3 are disposed. The opposite electrode 315 may be disposed on the bank layer 190 to cover the intermediate layers 1313 and 2313, each including the emission layer. For example, the opposite electrode 315 included in the first light-emitting element ED1 and the opposite electrode 315 included in the second light-emitting element ED2 may be integrally formed. The opposite electrode 315 may include a light-transmissive conductive layer including ITO, In₂O₃, or IZO, and may include a semi-transmissive layer including metal such as aluminum (Al) or silver (Ag). For example, the opposite electrode 315 may be a semi-transmissive layer including MgAg.

Because holes supplied from the first pixel electrode 1311 and electrons supplied from the opposite electrode 315 may form excitons in the emission layer, the first light-emitting element ED1 may allow light to be generated in the emission layer. As described above, a portion of light generated in the emission layer of the first intermediate layer 1311 may progress along the front direction (e.g., +z direction) of the display panel 10, pass through the opposite electrode 315, and may exit the display panel 10, and another portion of the light may progress along the first direction (e.g., -z direction) towards the first pixel electrode 1311 and be reflected by the first pixel electrode 1311, progress towards the front direction (e.g., +z direction), pass through the opposite electrode 315, and may exit the dispolay panel 10.

However, a portion of light generated in the light layer may also progress along a lateral direction. FIG. 5 shows, for example, a progression path of light LT emitted from the emission layer and progressing in the lateral direction. In the display panel 10 according to an embodiment of the present disclosure, a portion of the first pixel electrode 1311 may be disposed on the inner surface of the intermediate insulating layer 180. Accordingly, as shown in FIG. 5, light LT emitted from the emission layer of the first intermediate layer 1313 and progressing in the lateral direction may be reflected by the first pixel electrode 1311, which is disposed on the sloped inner surface of the first insulating layer 1180 . The light LT may then progress in the front direction (e.g., +z direction) of the display panel 10. Likewise, light LT emitted from the emission layer of the second intermediate layer 2313 and progressing in the lateral direction may be reflected by the second pixel electrode 2311, which is disposed on the slopped inner surface of the second insulating layer 2180. The light LT may then progress in the front direction (e.g., +z direction) of the display panel 10.

In an embodiment of the present disclosure, an angle formed by the inner surface of the intermediate insulating layer 180 facing the bank layer opening 190OP and the upper surface of the planarization layer 170 may range from about 45° to about 75°. For example, an angle formed by the inner surface of the intermediate insulating layer 180 and the upper surface of the planarization layer 170 maximizes a light extraction efficiency may be about 60°. However, as described above, as a planar length of the inner surface of the intermediate insulating layer 180 increases, a slope of the inner surface of the intermediate insulating layer 180 may decrease. In the case where the slope of the inner surface of the intermediate insulating layer 180 is formed excessively low, a light extraction efficiency may be reduced. Accordingly, in the display panel 10 according to an embodiment of the present disclosure, because the intermediate insulating layer 180 may include the first insulating pattern 1180 and the second insulating pattern 2180, the slope of the inner surface of the intermediate insulating layer 180 may increase, and thus, a light extraction efficiency may increase.

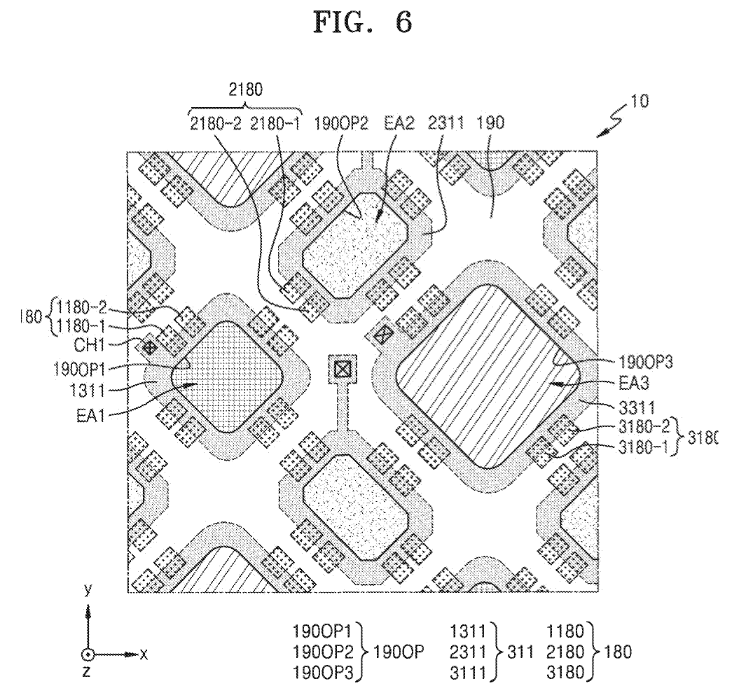

FIG. 6 is a plan view of the display panel 10 according to an embodiment of the present disclosure. Referring to FIG. 6, the other characteristics except for the characteristics of the intermediate insulating layer 180 are the same as those described with reference to FIGS. 4 and 5. To the extent that an element has not been described in detail, it may be assumed that the element is at least similar to corresponding elements that have been described in FIGS. 4 and 5.

Referring to FIG. 6, the intermediate insulating layer 180 may be disposed between the substrate 100 (see FIG. 5) and the bank layer 190. The intermediate insulating layer 180 may be disposed adjacent to the bank layer opening 190OP, but apart from the bank layer opening 190OP in a plan view. The pixel electrode 311 may extend to be disposed on the intermediate insulating layer 180. Through this structure, light LT emitted from the emission layer and progressing in a lateral direction may be reflected by the pixel electrode 311 positioned on the inner surface of the intermediate insulating layer 180 and then may progress in a front direction (e.g., z direction) of the display panel 10.

In an embodiment of the present disclosure, the intermediate insulating layer 180 may include an insulating pattern 1180, 2180, and 3180 overlapping a partial region of the lateral surface of the bank layer opening 190OP in a plan view. For example, the intermediate insulating layer 180 may include a first insulating pattern 1180 overlapping a partial region of the lateral surface of the first bank layer opening 190OP1 in a plan view. Likewise, the intermediate insulating layer 180 may include a second insulating pattern 2180 overlapping a partial region of the lateral surface of the second bank layer opening 190OP2, and a third insulating pattern 3180 overlapping a partial region of the lateral surface of the third bank layer opening 190OP3 in a plan view.

In an embodiment of the present disclosure, the insulating pattern 1180, 2180, and 3180 may include a plurality of sub-patterns disposed apart from each other. For example, the plurality of sub-patterns 11800-1, 1180-2, 2180-1, 2180-2, 3180-1, and 3180-2 may be disposed on one lateral surface of the bank layer opening 190OP. For example, the first insulating pattern 1180 may include a first-1 sub-pattern 1180-1 and a first-2 sub-pattern 1180-2 disposed apart from each other. Likewise, the second insulating pattern 2180 may include a second-1 sub-pattern 2180-1 and a second-2 sub-pattern 2180-2 disposed apart from each other. The third insulating pattern 3180 may include a third-1 sub-pattern 3180-1 and a third-2 sub-pattern 3180-2 disposed apart from each other.

In an embodiment of the present disclosure, the first insulating pattern 1180 including the first-1 sub-pattern 1180-1 and the first-2 sub-pattern 1180-2 may overlap about 30 % to about 75 % of the lateral surface of the first bank layer opening 190OP1. Likewise, the third insulating pattern 3180 including the third-1 sub-pattern 3180-1 and the third-2 sub-pattern 3180-2 may overlap about 30 % to about 75 % of the lateral surface of the third bank layer opening 190OP3. In case where the second insulating pattern 2180 overlaps a long side of the second bank layer opening 190OP2, the second-1 sub-pattern 2180-1 and the second-2 sub-pattern 2180-2 may overlap about 30 % to about 75 % of the lateral surface of the second bank layer opening 190OP2. In case where the second insulating pattern 2180 overlaps a short side of the second bank layer opening 190OP2, the second-1 sub-pattern 2180-1 and the second-2 sub-pattern 2180-2 may overlap about 75 % to about 100 % of the lateral surface of the second bank layer opening 190OP2. However, the embodiment is not necessarily limited thereto, and the second insulating pattern 2180 overlapping a short side of the second bank layer opening 190OP2 may include a single sub-pattern 2180-1 or 2180-2 instead of a plurality of sub-patterns 2180-1 and 2180-2.

As described above, because the intermediate insulating layer 180 may be disposed adjacent to the bank layer opening 190OP, light LT emitted in the lateral direction from the emission layer may be reflected by the pixel electrode 311 disposed on the inner surface of the intermediate insulating layer 180, and may be emitted to the front direction of the display panel 10. Accordingly, a light extraction efficiency may increase. In this case, the inner surface of the intermediate insulating layer 180 may be inclined such that light LT emitted to the lateral surface is reflected by the pixel electrode 311 and emitted to the front direction of the display panel 10. However, due to process characteristics, as a planar length of the inner surface of the intermediate insulating layer 180 increases, it may be difficult for the inner surface of the intermediate insulating layer 180 to have a high slope. For example, as the planar length of the inner surface of the intermediate insulating layer 180 is reduced, the slope of the inner surface of the intermediate insulating layer 180 may increase.

Accordingly, in the display panel 10 according to an embodiment of the present disclosure, because the insulating pattern 1180, 2180, and 3180 may include a plurality of sub-patterns 11800-1, 1180-2, 2180-1, 2180-2, 3180-1, and 3180-2 disposed apart from each other, a slope of the inner surface of the intermediate insulating layer 180 may increase the light extraction efficiency. For example, through the above structure, the display panel 10 according to an embodiment of the present disclosure may increase a light extraction efficiency by utilizing the sub-patterns 11800-1, 1180-2, 2180-1, 2180-2, 3180-1, and 3180-2 and adjusting the slope of the inner surface of the intermediate insulating layer 180.

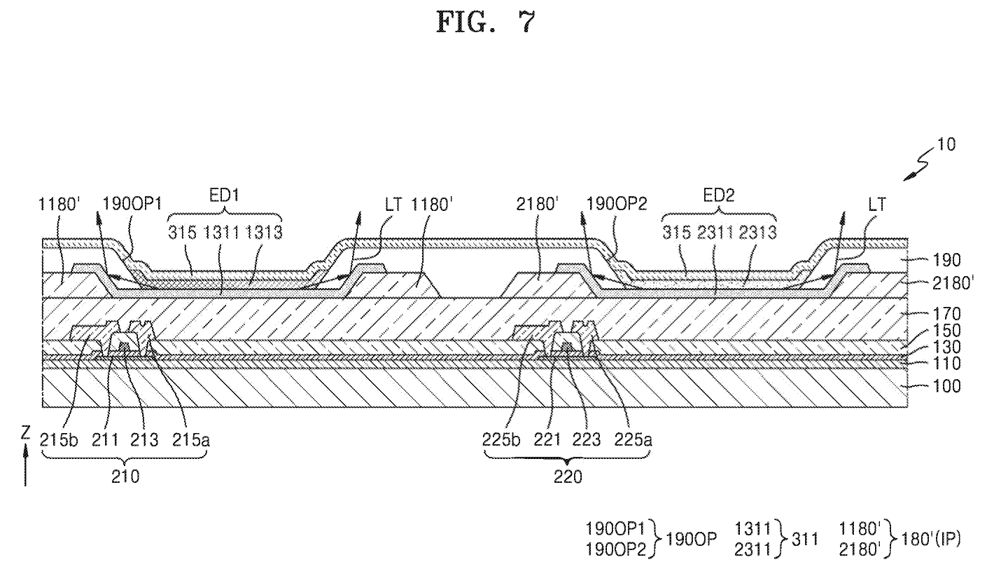

FIG. 7 is a cross-sectional view of the display panel 10 according to an embodiment of the present disclosure. Referring to FIG. 7, other characteristics except for those of the planarization layer 170 and an insulating pattern IP are the same as those described with reference to FIGS. 4 and 5. To the extent that an element has not been described in detail, it may be assumed that the element is at least similar to corresponding elements that have been described in FIG. 5.

Referring to FIG. 7, the planarization layer 170 may be disposed on the first thin-film transistor 210 and the second thin-film transistor 220. The first light-emitting element ED1, the second light-emitting element ED2, and the bank layer 190 may be disposed on the planarization layer 170. The planarization layer 170 may include an organic material, for example, acryl, benzocyclobutene (BCB), or hexamethyldisiloxane (HMDSO).

In an embodiment of the present disclosure, the planarization layer 170 may further include the insulating pattern IP formed on the upper surface of the planarization layer 170. For example, an intermediate insulating layer 180', including the insulating pattern IP may be integrally formed with the planarization layer 170. Accordingly, the intermediate insulating layer 180' may include the same material as that of the planarization layer 170. The intermediate insulating layer 180' including the insulating pattern IP may be formed through the same process as a process of forming the planarization layer 170.

For example, the insulating pattern IP may be formed by selectively exposing and developing the planarization layer 170 through a half-tone mask. The half-tone mask may be a mask with regions having different transmittances, which may include a light-blocking portion, a semi-transmissive portion, and a light-transmissive portion. The planarization layer 170 may be exposed to varying levels for each portion through the half-tone mask, and a portion of the planarization layer 170 may be removed through a developing process. The amount of the planarization layer 170 removed may vary depending on the exposure amount, and the patterned planarization layer 170 may have different thicknesses for each portion in a single process.

The insulating pattern IP may include a first insulating pattern 1180', which is formed adjacent to the first bank layer opening 190OP1 and a second insulating pattern 2180', which is formed adjacent to the second bank layer opening 190OP2. A portion of the edge of the first pixel electrode 1311 may be disposed on the first insulating pattern 1180', and a portion of the edge of the second pixel electrode 2311 may be disposed on the second insulating pattern 2180'. Even in this structure, light LT emitted from the emission layer and progressing in a lateral direction may be reflected by the pixel electrode 311 disposed on the inner surface of the insulating pattern IP and then may be emitted in the front direction (e.g., +z direction) of the display panel 10.

Accordingly, in the display panel 10 according to an embodiment of the present disclosure, because the insulating pattern IP may be formed on the planarization layer 170, process may be simplified and a light extraction efficiency may increase.

According to embodiments of the present disclosure, the display panel 10 with an increased light extraction efficiency and the electronic apparatus may be provided. The above effect is provided as an example, and the effect of the disclosure is not necessarily limited thereto.

It should be understood that embodiments described herein should be considered in a descriptive sense and not necessarily limited. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display panel, comprising:
a substrate;
a first pixel electrode disposed on the substrate;
a bank layer covering edges of the first pixel electrode, the bank layer including a first bank layer opening that exposes a central portion of the first pixel electrode; and
an intermediate insulating layer disposed between the substrate and the bank layer,
wherein the first pixel electrode extends over the intermediate insulating layer, and
wherein the intermediate insulating layer includes a first insulating pattern overlapping a part of a lateral surface of the first bank layer opening in a plan view.

2. The display panel of claim 1, wherein the first insulating pattern overlaps about 30 % to about 75 % of the lateral surface of the first bank layer opening facing the first insulating pattern.

3. The display panel of claim 1, wherein the first insulating pattern is spaced apart from the first bank layer opening.

4. The display panel of claim 1, wherein the first bank layer opening has, in a plan view, a quadrilateral shape, a shape that is similar to quadrilateral but with round corners, or a shape that is similar to quadrilateral but with chamfered edges.

5. The display panel of claim 1, wherein an end of the first pixel electrode extending towards a center of the lateral surface of the first bank layer opening is disposed on the first insulating pattern.

6. The display panel of claim 1, further comprising:
a thin-film transistor disposed on the substrate; and
a planarization layer covering the thin-film transistor and disposed under the first pixel electrode,
wherein the intermediate insulating layer is disposed on the planarization layer.

7. The display panel of claim 6, wherein an end of the first pixel electrode extending towards an edge of the first bank layer opening is disposed on the planarization layer.

8. The display panel of claim 6, wherein, in a cross-sectional view in a thickness direction of the substrate, an angle between a lateral surface of the first insulating pattern facing the first bank layer opening and an upper surface of the planarization layer ranges from about 45° to about 75°.

9. The display panel of claim 1, further comprising a second pixel electrode disposed on the substrate, adjacent to the first pixel electrode,
wherein the bank layer further includes a second bank layer opening that exposes a central portion of the second pixel electrode, and
wherein the intermediate insulating layer further includes a second insulating pattern overlapping a part of a lateral surface of the second bank layer opening.

10. The display panel of claim 9, wherein the first insulating pattern and the second insulating pattern are spaced apart from each other.

11. The display panel of claim 9, wherein the second bank layer opening includes a first lateral surface and a second lateral surface, with a length greater than a length of first lateral surface, and
wherein a ratio of a region corresponding to the second insulating pattern to the first lateral surface is different from a ratio of a region corresponding to the second insulating pattern to the second lateral surface.

12. The display panel of claim 11, wherein the second insulating pattern overlaps about 30 % to about 75 % of the second lateral surface.

13. The display panel of claim 11, wherein the second insulating pattern overlaps about 75 % to about 100 % of the first lateral surface.

14. The display panel of claim 1, wherein the first insulating pattern includes a first sub-pattern and a second sub-pattern that are spaced apart from each other.

15. The display panel of claim 1, further comprising:
a thin-film transistor disposed on the substrate; and
a planarization layer covering the thin-film transistor and disposed under the first pixel electrode,
wherein the intermediate insulating layer and the planarization layer are integrated into a single structure.

16. An electronic apparatus, comprising:
a processor;
a memory having stored application programs for execution by the processor;
a display device, comprising:
a display panel comprising:
a substrate;
a first pixel electrode disposed on the substrate;
a bank layer covering edges of the first pixel electrode, the bank layer including a first bank layer opening that exposes a central portion of the first pixel electrode; and
an intermediate insulating layer disposed between the substrate and the bank layer, and
wherein the first pixel electrode extends over the intermediate insulating layer,
wherein the intermediate insulating layer includes a first insulating pattern overlapping a part of a lateral surface of the first bank layer opening in a plan view.

17. The electronic apparatus of claim 16, wherein the first insulating pattern overlaps about 30 % to about 75 % of the lateral surface of the first bank layer opening facing the first insulating pattern.

18. The electronic apparatus of claim 16, further comprising:
a thin-film transistor disposed on the substrate; and
a planarization layer covering the thin-film transistor and disposed under the first pixel electrode,
wherein the intermediate insulating layer is disposed on the planarization layer.

19. The electronic apparatus of claim 18, wherein in a cross-sectional view in a thickness direction of the substrate, an angle between a lateral surface of the first insulating pattern facing the first bank layer opening and an upper surface of the planarization layer ranges from about 45° to about 75°.

20. The electronic apparatus of claim 16, wherein the first insulating pattern includes a first sub-pattern and a second sub-pattern that are spaced apart from each other.
